(19) United States
(12) Patent Application Publication
(10) Pub. No.: US 2015/0187628 A1
(43) Pub. Date: Jul. 2, 2015

(54) Vacuum Device by Using Centrifugal Resources

(71) Applicant: National Tsing Hua University, Hsin Chu City (TW)

(72) Inventor: Dongliang Daniel SHEU, Hsin Chu (TW)

(21) Appl. No.: 14/657,660

(22) Filed: Mar. 13, 2015

Related U.S. Application Data
(63) Continuation of application No. 13/352,032, filed on Jan. 17, 2012.

(30) Foreign Application Priority Data
Mar. 24, 2011 (TW) 100110228

(51) Int. Cl. H01L 21/683; B24B 1/00

(52) U.S. Cl. CPC H01L 21/6838; B24B 1/00

(57) ABSTRACT

A wafer holding vacuum for a wafer polishing system and the wafer suction device for CMP (Chemical Mechanical Polishing) by utilizing existing resources provided by the rotating polishing post is provided. The device introduces a channel configured in the wafer suction device. One end of the channel is exposed at downside of the holding block, and another end of the tube is exposed at lateral side of the holding block. By aforementioned configuration, the channel can suck gas and/or liquid between the wafer and the device, and can discharge them to the outer environment at the lateral side using centrifugal force naturally provided by the polishing post.

### CROSS-REFERENCE TO RELATED APPLICATIONS

The application is a continuation application of application Ser. No. 13/352,032, filed on Jan. 17, 2012.

### FIELD OF THE INVENTION

The present invention generally relates to a method of using existing resources to generate vacuum for holding wafer or discharging fluid during wafer polishing processes. This is related to a wafer suction method using existing block.

### DESCRIPTION OF THE PRIOR ART

CMP (Chemical Mechanical Polishing) has become an indispensable process in the semiconductor industry due to ever-shrinking feature size of circuits. FIG. 1 shows a conventional CMP system. The system includes a polishing platform 50, a block 56, and a rotary driving unit 52 connected to the block 56. In this case, the polishing platform 50 is utilized to hold and fix the wafer 36. A polishing pad 50a on the surface of the polishing platform 50 performs the polishing function on the wafer 36 either it is on the active layer of the wafer or on its back side for various purposed. The rotary driving unit 52 is employed to rotate the block 56 which, in turn, rotates the wafer. In generally, the polishing slurry is added during the process of which the main ingredients contain gelled particles and proper chemical reagents. When the wafer constrained by the polishing post is rotated relative to the polishing pad, the surface of the wafer may be planarized by both chemical and mechanical means. Further, the leftover defects of the prior processes on the wafer, such as scratches, stains, and cavities may be removed.

FIG. 2 exhibits the cross-section diagram of a conventional polishing post. As shown, the structural body 104 is the main structure on the upper level of the polishing post. The structural body 104 is connected to a perforated plate 108 through an inner tube 106, and a chamber 103 capable of containing air is consequently formed. An elastic film 113 is further introduced under the lower surface of the perforated plate 108 across the buffer ring 110, and the fixing ring 112 can be used to fix the relative position among the perforated plate 108, the buffer ring 110, and the elastic film 113.

Referred to FIG. 3, the figure illustrates the front and top view of the perforated plate 108. As shown, the perforated plate 108 is a circular plate with plural holes 115 on the surface. Referred back to FIG. 1, as the wafer being sucked by the polishing post, the lower surface of the elastic film 113 is attached to the wafer 114 at first. Because the inner tube 106 is an inflatable airbag, it can press downwards through the perforated plate 108 and the buffer circle 110 when inflated, so that the elastic film 113 can be tightly adhered to the wafer 114. Then, the air pipe 102 can be used to suck the air from the chamber 103, such that the elastic film 113 may cave towards the holes 115 of the perforated plate 108, thereby forming plural vacuum chambers on the backside of the wafer 114 and achieving the effect of sucking the wafer.

However, the vacuum source is indispensable in the traditional vacuum suction device. Because the polishing post is rotating during the process, there are two main issues regarding this conventional vacuum suction device: 1. the vacuum pipe has to be configured at the center of the rotary mechanism, which means it has to pass through various complicated elements in the polishing post, so that the manufacturing process becomes difficult and the cost also becomes higher. Additionally, there may exist some gaps since the air pipe are configured between fixed elements and rotary elements, thereby causing air leaking into the vacuum and consequently wasting the vacuum energy. 2. The conventional polishing device requires continuous vacuum energy to maintain the process. Some liquid or gas may leak into the space between the backside of the wafer and the block during polishing. If the vacuum energy is stopped, the liquid or gas leaked into the back of the wafer may loosen the wafer even causing it to be thrown from the block during rotation. This often causes wafer breakage.

Based on aforementioned descriptions, a new configuration is needed to alleviate the wafer breakage issue in the CMP process.

### SUMMARY OF THE INVENTION

In view of the foregoing, the present invention provides a device capable of maintaining vacuum without any vacuum energy, and it can employ the existing rotary resources, intended for polishing wafer not discharging fluid, to generate and maintain the vacuum, thereby significantly saving energy and simplifying the complexity of manufacturing this apparatus. The manufacturing of the apparatus is simple. For an existing block, simply drill some holes (channels) on the block according to the FIGS. 5 and 6. For a new block, the generation of the channels can be embedded in the molding process by mold design without adding any additional cost to the manufacturing process such as casting. In fact the material usage can even be reduced by the volume occupied by the channels. In contrast, the conventional vacuum line through the center of the polishing post will involve complex and precise drilling through many conponents in which vacuum leakage between adjacent rotating components will be inevitable causing energy loss.

It was realized that the reason of wafer breakage is due to the shortage of the vacuum strength between the wafer and the contacting surface on the block. Maintaining the continuous vacuum strength requires continuous vacuum energy and complicated polishing post design to support the continuous vacuum under leakage. Therefore, the present invention provides a simple way of holding block design without the need of continuous vacuum energy supplies. The vacuum between the back of the wafer surface and the polishing block is provided by the centrifugal force provided by polishing post rotation already existent intended for polishing wafer instead of generating centrifugal force.

One advantage of the present invention is to utilize the natural centrifugal force generated when the polishing post is rotated for polishing purpose, so as to maintain the vacuum, thereby preventing the breakage issue that the wafer is thrown away during the polishing process while reducing the cost of existing continuous vacuum line operations.

Another advantage of the present invention is to provide a wafer suction device with simplified structure and excellent effect, thereby achieving the objective of saving cost and resources. The more complex the system design the more error prone the system is. Conventional vacuum line has to go through all the components along the central line of polishing post/post on FIGS. 1-4. There are many places for errors such as blockage of the channels, channel leakages, etc. The present invention involves only a few lines of channel all within the polishing block greatly reducing the locations for errors and the manufacturing cost of the vacuum device.

In order to meet aforementioned purposes, the present invention provides a wafer suction device, which includes: a block; and at least one channel configured in the block, one end of the at least one channel is exposed at down side of the block, whereby utilizing centrifugal force to suck fluid (including gas and/or liquid) between the block and the wafer, and another end of the at least one channel is exposed at lateral side of the block, whereby discharging the fluid. By aforementioned configuration, the present invention can employs the centrifugal force naturally generated to suck the leaked-in fluid between the wafer and the block and discharge the fluid to environment through the channels when the polishing post is rotated. The vacuum effect can be achieved without any vacuum source. Thus, it can save a lot of costs associated with the generation and maintenance of the conventional vacuum system such as pumps, storage systems, filters, vacuum lines, regular maintenances, etc. Further, because the polishing post is always rotating during the polishing processes, the centrifugal force may be maintained continuous thus the vacuum is reserved continuously holding the wafer firmly to avoid being thrown out.

The present invention also provides a wafer suction device, which comprises: a block; at least one main channel configured in the block, and one end of the at least one main channel is exposed at lateral side of the block; at least one first sub-channel, wherein one end is exposed at down side of the block and, and another end is connected to another end of the at least one main channel; and at least one second sub-channel, wherein one end is exposed at down side of the block, and another end is connected to body of the at least one main channel; wherein connected zones between the at least one main channel and the at least one second sub-channel are formed as a Venturi tube. In view of the foregoing, the present invention can utilize the Venturi tube at the connected zones between the main channel and the second sub-channel to increase the flowing speed of the fluid, whereby facilitating to generate and maintain the vacuum.

To prevent the reverse fluid flow in the block channel when the polishing post is not rotating, the present invention employs a check valve at the end of the channel thereby preserving the vacuum to hold the wafer in place.

Additionally, in order to prevent the fluid from spraying around, the present invention may also introduce a fluid-guiding device at the exit of the channel, so that the fluid can be directed downwards to join the recovered polishing fluid to be discharged.

### BRIEF DESCRIPTION OF THE DRAWINGS

FIG. 1 shows a conventional CMP system;

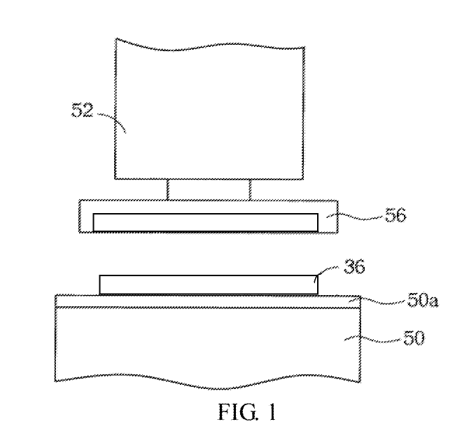

FIG. 2 shows a conventional polishing post;

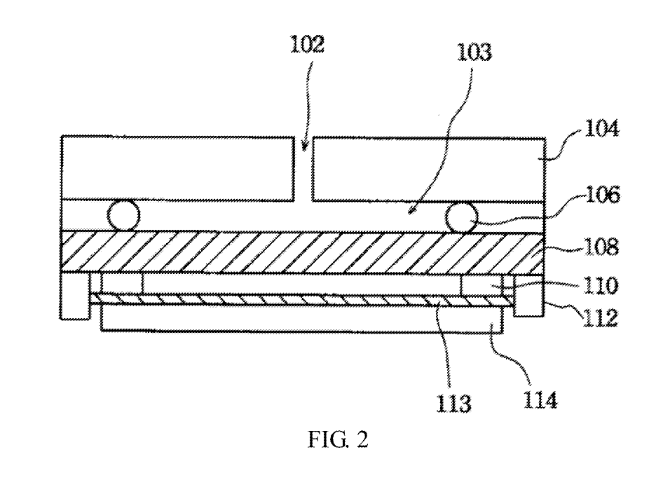

FIG. 3 shows the top and front view of the perforated plate of the conventional polishing post;

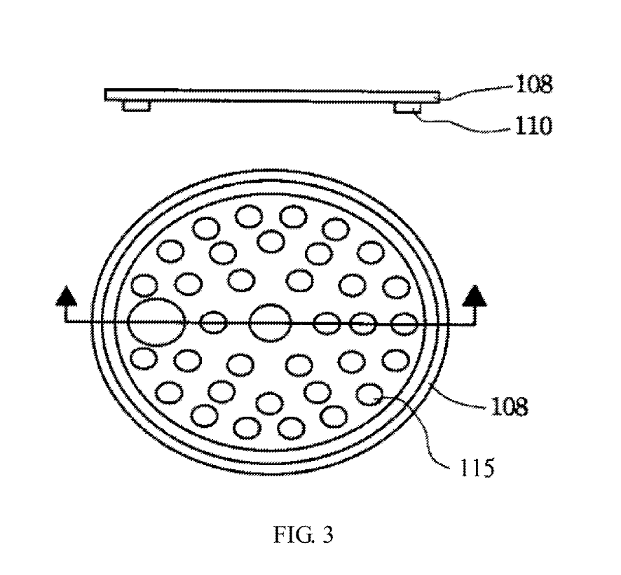

FIG. 4 shows the wafer polishing system of the present invention;

FIG. 5 shows the cross-section diagram of the wafer suction device of the present invention;

FIG. 6 shows the top view of the wafer suction device of the present invention;

FIG. 7 shows the enlarged diagram of the joint 405 of the present invention.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

The present invention relates to a wafer suction device of the polishing post. Generally speaking, the present invention introduces at least one channel in the block of the wafer suction device, wherein one end is exposed at down side of the block, and another side is exposed at lateral side of the block. By aforementioned configuration, the gas and/or liquid between the wafer and the block are sucked to the environment by the induced centrifugal force generated in the channel when the polishing post is being rotated. When the gas and/or liquid are sucked out the vacuum status is created. Therefore, the vacuum sucking force can be generated to enable wafer adherence to the polishing post thus preventing the wafer breakage. When the CMP is polishing the wafer, due to turning and vibrating air and liquid occasionally sip into the contact between the holding block and the back side of the wafer causing the holding block unable to hold the wafer firmly. This is the main cause for wafer to get loose and break out.

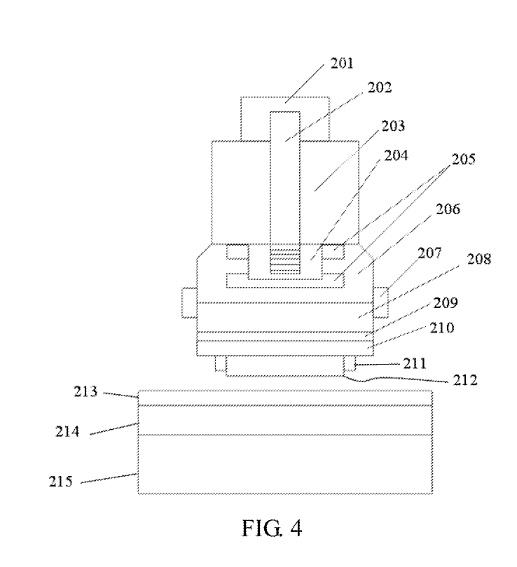

Referred to FIG. 4, this figure exhibits the preferred embodiment of the wafer polishing system of the present invention. In this embodiment, the motor 201 is configured above the cylinder 203 for driving the shaft 202 to rotate. The rotary bearing 204 is connected to another end of the shaft 202. Two shaft bearings 205 are respectively configured at upper and lower side of the rotary bearing 204. The polishing post body (PP head) 206 is configured under the cylinder 203. A ring 207 surrounds the body of polishing post 206 and the block 208 under the polishing post body 206. The glued layer 209 is coated at the bottom of the block 208, and the nap layer 210 is adhered under the glued layer 209 to suck the wafer 212. The fixing ring 211, which is preferably composed of fiber glass, is configured at the bottom of the nap layer 210 to encircle the wafer 212. Aforementioned block 208 is the main component of the wafer suction device, and the specifically improved structure will be expounded in the following specification. Additionally, a polishing pad 213 on top of a plate 214 and are positioned on the polishing platform 215. The polishing pad will polish the wafer 212.

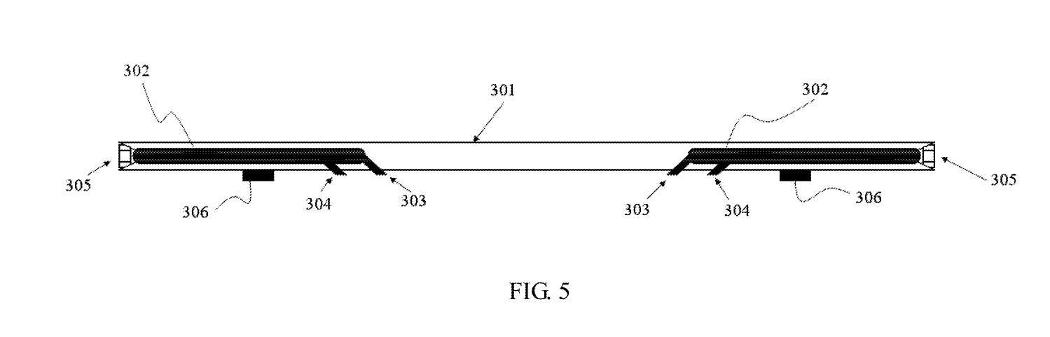

The preferred embodiment of the wafer suction device of the present invention is shown in FIG. 5. The cross-sectional diagram of the wafer suction device is made out of the regular block. The device comprises a block 301, at least one main channel 302, at least one first sub-channel 303, at least one second sub-channel 304, at least one check valve 305, and a fixing ring 306. In this case, the main channel 302 is configured in the block 301, wherein one end is exposed out of the lateral side of the block 301 to discharge the fluid sucked in via the centrifugal force. The first sub-channel 303 is connected to another end of the main channel 302, and preferably, they are connected radially in an outward skew angle to bring about centrifugal force for sucking the fluid. The second sub-channel 304 is connected to the body of the main channel 302, and preferably, they are also connected radially in an outward skew angle to facilitate the fluid to flow when the device is rotating. By aforementioned combination of the main channel 302, the first sub-channel 303 and the second sub-channel 304, it can provide a path for fluid (including gas and liquid) to flow, so that the wafer suction device can suck the fluid between the wafer and the block when the device is rotating. The check valve 305 is configured at the outer end of the main channel 302. The check valve allows the fluid to flow from the main channel 302 to the environment while prevent the fluid from flowing back form the environment to the main channel 302, thereby maintaining the vacuum status inside the channels. The fixing ring 306, preferably made of fiber glass, is configured at the bottom of the block 301 for holding the wafer. In this embodiment, the ends of the first and second sub-channels 303, 304 are both exposed at the bottom of the block 301, and more specifically, it is exposed at the contact surface between the block 301 and the wafer (not shown in the figure). When the polishing post is under rotation, the wafer suction device is rotating with the polishing post thus generating centrifugal force. This enables the first and second sub-channels 303, 304 to suck the fluid residing between the block and the wafer by the generated centrifugal force and discharge it out of the block through the connected channels. In the prior related art, some researches also discovered that the wafer breakage issue is caused by the insufficient vacuum force and tried to resolve this issue by introducing vacuum in various ways. For instance, the U.S patent application 20070197141 entitled “Polishing apparatus with grooved subpad”, which employs a vacuum source for gaining force to maintain the vacuum. The distinguishing feature of the present invention, nevertheless, is to employ the existing resources, the centrifugal force, when the polishing post is under rotation to maintain the vacuum instead of requiring any vacuum source. Compared to aforementioned U.S patent application and the similar prior art, the present invention not only maintains the vacuum status, but also saves resources and cost more effectively.

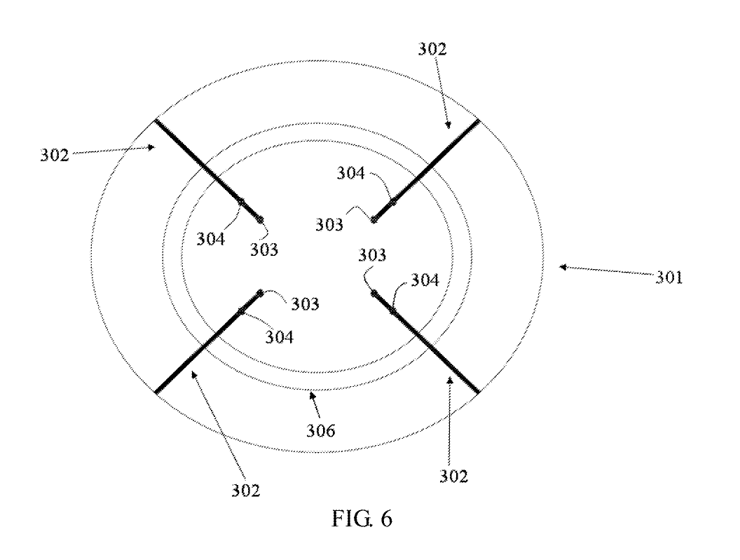

FIG. 6 shows the top view of a sample wafer suction device of the present invention. As shown, four main channels 302 with ends exposed at lateral side of the block 301 are respectively distributed in the block 301. Each main channel 302 is connected to a first and a second sub-channels 303, 304, which are both exposed under the block 301. Notice that the quantities of aforementioned main channel 302, the first sub-channel 303 and the second sub-channel 304 are just to explain, not to limit the present invention. The user can choose appropriate quantities depending on the demand. As shown in the figure, the length of the main channel 302 is shorter than the radius of the block 301, so as to facilitate the centrifugal effect more effectively.

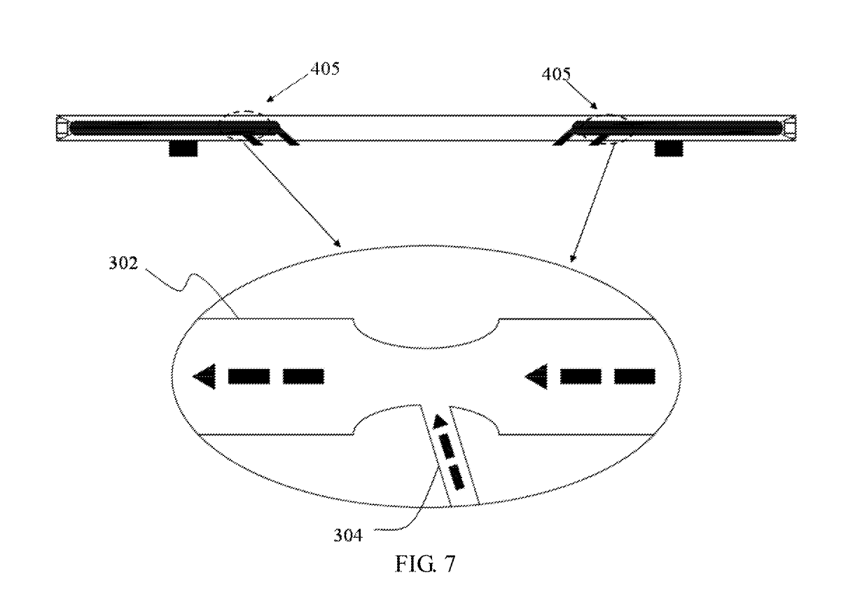

Referred to FIG. 7, it depicts another embodiment of the joint between the main channel 302 and the second sub-channel 304. The joint 405 can be focused hereinafter. As shown, when the cross-section of the main channel 302 gets nearer to the second sub-channel 304, the radius is shorter, thereby forming a Venturi tube to make the suck more efficient. More specifically, the main channel 302 is tapered as arc at the joint 405. Because the cross-section is reduced in the middle, the flowing speed can consequently be increased and pressure decrease based on Bernoulli equation. This will improve the sucking rate of the fluid. By introducing the Venturi tube, the speed and quality of forming the vacuum can further be elevated.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. A method for discharging fluid during wafer chemical mechanical polishing, comprising:
providing a block; and
a polishing post body which is under rotation for other existing purpose not intended for discharging fluid, wherein one end of at least one channel is exposed at a contact surface between said block and a wafer, whereby utilizing existing centrifugal force created by said rotating polishing post body to suck fluid between said block and said wafer, and another end of said at least one channel is exposed at lateral side of said block, whereby discharging said fluid.

2. The method according to claim 1, further providing at least one check valve configured at said another end of said at least one channel.

3. The method according to claim 1, wherein a fluid-guiding device is configured at an exit of said channel, whereby making said fluid outflows along a specific direction.

4. The method according to claim 1, wherein said at least one channel having a main channel and at least one sub-channel connected to said main channel, and one end of said main channel is exposed at said lateral side of said block, one end of said at least one sub-channel is exposed to said contact area between said block and said wafer, and another end of said at least one sub-channel is connected to said main channel for discharging said fluid.

5. The method according to claim 4, wherein connected zones between said main channel and said at least one sub-channel are formed as a Venturi tube.

6. The method according to claim 4, wherein said at least one sub-channel is non-vertically connected to said main channel.

7. The method according to claim 4, further providing at least one check valve configured at one end of said main channel.

8. The method according to claim 4, wherein a fluid-guiding device is configured at an exit of said main channel, whereby making said fluid discharged along a specific direction.

9. The method according to claim 1, further providing a fixing ring configured at down side of said block for fixing said wafer.

10. A method for holding wafer using suction during wafer chemical mechanical polishing, comprising:
providing a wafer suction device configured at bottom of a polishing post body for attaching a wafer;
wherein said wafer suction device comprises a block and at least one channel configured in said block, and one end of said at least one channel is exposed at a contact surface between said block and said wafer; and
a polishing post body which is under rotation for other existing purpose not intended for sucking wafer, whereby utilizing existing centrifugal force created by said polishing post body to suck fluid between said block and said wafer, and another end of said at least one channel is exposed at lateral side of said block, whereby discharging said fluid to generate vacuum for sucking said wafer.

11. The method according to claim 10, wherein said at least one channel having a main channel and at least one sub-channel connected to said main channel, and one end of said main channel is exposed at said lateral side of said block, one end of said at least one sub-channel is exposed to said contact area between said block and said wafer, and another end of said at least one sub-channel is connected to said main channel for discharging said fluid.

12. The method according to claim 11, wherein connected zones between said main channel and said at least one sub-channel are formed as a Venturi tube.

13. The method according to claim 11, wherein said at least one sub-channel is non-vertically connected to said main channel.

14. The method according to claim 10, further providing at least one check valve configured at one end of said main channel.

15. The method according to claim 10, wherein a fluid-guiding device is configured at an exit of said main channel, whereby making said fluid discharged along a specific direction.

16. The method according to claim 10, further providing at least one check valve configured at said end of said at least one main channel.

17. The method according to claim 10, wherein a fluid-guiding device is configured at an exit of said main channel, whereby making said fluid discharged along a specific direction.

18. The method according to claim 10, further providing a fixing ring configured at down side of said block for fixing said wafer.
